(19) United States
(12) Patent Application Publication
(10) Pub. No.: US 2016/0197273 A1
(43) Pub. Date: Jul. 7, 2016

(54) SEMICONDUCTOR ELEMENT AND SEMICONDUCTOR DEVICE

(71) Applicant: KABUSHIKI KAISHA TOSHIBA, Tokyo (JP)

(72) Inventors: Junichi WADA, Yokkaichi (JP); Yoshio OZAWA, Yokkaichi (JP)

(21) Appl. No.: 15/069,641

(22) Filed: Mar. 14, 2016

Related U.S. Application Data
(62) Division of application No. 14/307,739, filed on Jun. 18, 2014.

(30) Foreign Application Priority Data
Jun. 20, 2013 (JP) 2013-130028

(51) Int. Cl. H01L 45/00

(52) U.S. Cl. CPC H01L 45/1273; H01L 45/146; H01L 45/1246; H01L 45/1633; H01L 45/1233; H01L 45/08

(57) ABSTRACT

A semiconductor element includes a first electrode having at least one convex feature, a second electrode having a concave feature opposed to the convex feature, and a variable resistance layer including an element whose absolute value of standard reaction Gibbs energy for forming oxide is larger than the corresponding value of an element included in the first electrode, and being disposed between the convex feature and the concave feature or on the outer circumference of the convex feature of the first electrode.

### CROSS-REFERENCE TO RELATED APPLICATION

This application is a division of U.S. patent application Ser. No. 14/307,739, filed on Jun. 18, 2014, which is based upon and claims the benefit of priority from Japanese Patent Application No. 2013-130028, filed Jun. 20, 2013, the entire contents of each of which are incorporated herein by reference.

### FIELD

Embodiments described herein relate generally to a semiconductor element and a semiconductor device.

### BACKGROUND

An example of resistance variable type memory cell arrays includes a plurality of horizontal electrodes extending in the horizontal direction, and a plurality of vertical electrodes extending in the vertical direction. These horizontal electrodes and vertical electrodes are disposed so as to cross each other at crossing points, and variable resistance layers are sandwiched between the horizontal electrodes and the vertical electrodes.

One problem that arises from the use of this type of structure, for example, is that a leakage current that is more than a negligible amount flows in non-selected cells at the time of a data read, data write, or other similar operation that is performed on the selected cells. In such a case, the power consumption of the memory cell array increases as number of memory cells increases within the structure.

### DESCRIPTION OF THE DRAWINGS

FIG. 1 is a cross-sectional view illustrating the structure of a semiconductor element 1a according to a first embodiment.

FIGS. 2A through 2D are enlarged cross-sectional views illustrating the operation of the semiconductor element 1a according to the first embodiment.

FIG. 3 is a cross-sectional view illustrating the structure of a semiconductor element 1b according to a second embodiment.

FIG. 4 is a cross-sectional view illustrating the structure of a semiconductor element 1c according to a third embodiment.

FIG. 5 is a cross-sectional view illustrating the structure of a semiconductor element 1d according to a fourth embodiment.

FIG. 6 is a cross-sectional view illustrating the structure of a semiconductor element 1e according to a modified example of the fourth embodiment.

FIG. 7 is a bird's eye view illustrating the structure of a semiconductor device 2a according to a fifth embodiment.

FIG. 8A is a plan view illustrating the structure of the semiconductor device 2a according to the fifth embodiment.

FIG. 8B is a cross-sectional view illustrating a cross section taken along a line A-A′ in FIG. 8A.

FIG. 9A is a plan view illustrating the structure of the semiconductor device 2a in a reset condition according to the fifth embodiment.

FIG. 9B is a cross-sectional view illustrating a cross section in the reset condition taken along a line B-B′ in FIG. 9A.

FIG. 10A is a plan view illustrating the structure of a semiconductor device 2b according to a sixth embodiment.

FIG. 10B is a cross-sectional view illustrating a cross section taken along a line C-C′ in FIG. 10A.

FIG. 11A is a plan view illustrating the structure of the semiconductor device 2b in the reset condition according to the sixth embodiment.

FIG. 11B is a cross-sectional view illustrating a cross section in the reset condition taken along a line D-D′ in FIG. 11A.

FIG. 12A is a plan view illustrating the structure of a semiconductor device 2c according to a seventh embodiment.

FIG. 12B is a cross-sectional view illustrating a cross section taken along a line E-E′ in FIG. 12A.

FIG. 13A is a plan view illustrating the structure of a semiconductor device 2d according to an eighth embodiment.

FIG. 13B is a cross-sectional view illustrating a cross section taken along a line F-F′ in FIG. 13A.

FIG. 14A is a plan view illustrating the structure of a semiconductor device 2e according to a ninth embodiment.

FIG. 14B is a cross-sectional view illustrating a cross section taken along a line G-G′ in FIG. 14A.

FIG. 15 is a bird's eye view illustrating the structure of a semiconductor device 2f according to a tenth embodiment.

FIG. 16A is a plan view illustrating the structure of the semiconductor device 2f according to the tenth embodiment.

FIG. 16B is a cross-sectional view illustrating a cross section taken along a line H-H′ in FIG. 16A.

FIG. 17 is a cross-sectional view illustrating a cross section of a semiconductor device 2g according to a modified example of the tenth embodiment.

FIG. 18 is a cross-sectional view illustrating the structure of a semiconductor element if according to a modified example of the first embodiment.

### DETAILED DESCRIPTION

Embodiments of the disclosure provide a semiconductor element and a semiconductor device capable of reducing power consumption, and enlarging the device's memory capacity.

In general, according to one embodiment, a semiconductor element includes: a first electrode including at least one convex feature; a second electrode including a concave feature opposed to the convex feature; and a variable resistance layer including an element whose absolute value of standard reaction Gibbs energy for forming an oxide is larger than the corresponding Gibbs energy value for forming an oxide with an element included in the first electrode, and wherein the variable resistance layer is disposed between the convex feature and the concave feature.

According to one embodiment, a semiconductor device includes: a first electrode extending in the vertical direction and having a convex feature; a second electrode disposed in the horizontal direction in such a position as to cross the first electrode, and having a concave feature opposed to the convex feature; and a variable resistance layer including an element whose absolute value of standard reaction Gibbs energy for forming an oxide is larger than the corresponding Gibbs energy value for forming an oxide with an element included in the first electrode, and wherein the variable resistance layer is disposed between the convex feature and the concave feature or on the outer circumference of the convex feature of the first electrode.

Embodiments of the invention may further provide a method of forming a semiconductor device, that comprises forming a first electrode that has a surface that has at least one convex feature formed thereon, wherein the first electrode comprises a first element, forming a variable resistance layer over the surface of the first electrode, wherein the variable resistance layer comprises a second element whose absolute value of standard reaction Gibbs energy for forming an oxide is larger than the corresponding absolute value of standard reaction Gibbs energy for forming an oxide by the first element, and forming a second electrode over at least a portion of the variable resistance layer that is disposed over the at least one convex feature formed on the first electrode.

Exemplary embodiments are hereinafter described with reference to the drawings. In the following description, similar parts shown in any of the drawings are given similar reference numbers. The dimensional ratios of respective parts are not limited to the ratios shown in the drawings. The respective embodiments are presented as an example only.

### First Embodiment

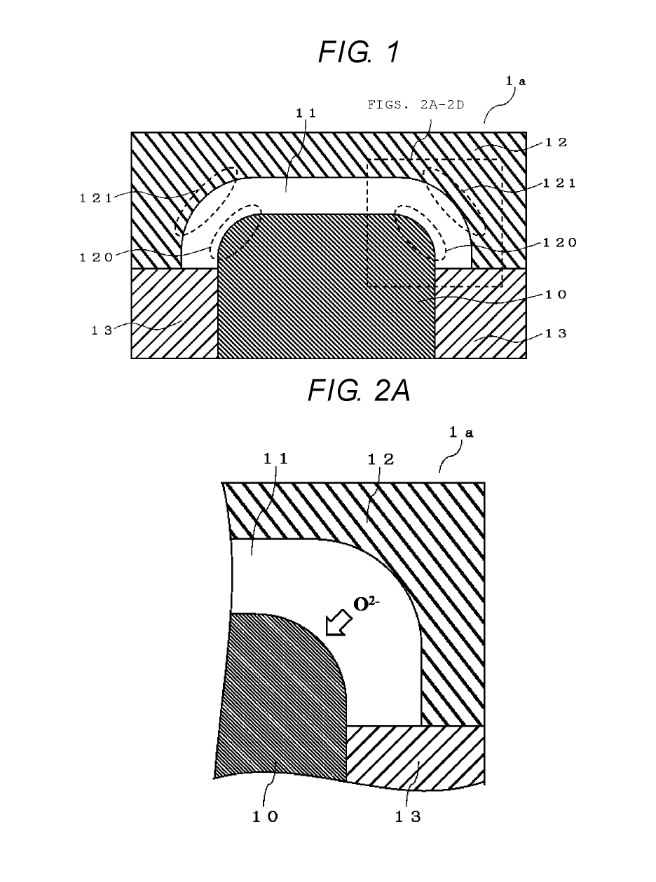

The structure of a semiconductor element 1a according to a first embodiment is now explained with reference to FIG. 1. FIG. 1 is a cross-sectional view showing the structure of the semiconductor element 1a according to an embodiment of the disclosure provided herein.

The semiconductor element 1a includes a first electrode 10, a variable resistance film 11, a second electrode 12, and element separating insulation films 13.

As illustrated in FIG. 1, the first electrode 10 which is provided with a convex feature 120 is sandwiched between the element separating insulation films 13. The variable resistance film 11 is disposed on the first electrode 10. The second electrode 12 which has a concave feature 121 opposed to the convex feature 120 is disposed on the variable resistance film 11. In some embodiments, the variable resistance film 11, or variable resistance layer, includes a metal oxide.

It is assumed herein that an absolute value of the standard reaction Gibbs energy (e.g., Gibbs free energy) required by a metal element, which constitutes the variable resistance film 11, for forming an oxide (hereinafter referred to as “standard reaction Gibbs energy”) is |ΔG₁|, and that an absolute value of standard reaction Gibbs energy required by a metal element constituting the first electrode 10 to form an oxide is |ΔG₂|. According to the semiconductor element 1a in this embodiment, the materials forming the variable resistance film 11 and the first electrode 10 are selected such that the value |ΔG₁| is larger than the value |ΔG₂|. Therefore, the metal element in the first electrode 10 and the metal element in the variable resistance film 11 have the relationship |ΔG₂|<|ΔG₁|. The semiconductor element 1a used herein is an element constructed as above.

In order to satisfy the relationship |ΔG₂|<|ΔG₁| between the first electrode 10 and the variable resistance film 11, titanium (Ti), silicone (Si), vanadium (V), tantalum (Ta), manganese (Mn), niobium (Nb), chromium (Cr), tungsten (W), molybdenum (Mo), iron (Fe), or the like is used as the metal element constituting the variable resistance film 11. On the other hand, in order to satisfy the relationship |ΔG₂|<|ΔG₁| for the standard reaction Gibbs energy, aluminum (Al), Ti, Si, Ta, Mn, Nb, Cr, W, Mo, Fe, cobalt (Co), nickel (Ni), rhenium (Re), copper (Cu), ruthenium (Ru), cerium (Ce), iridium (Ir), palladium (Pd), and silver (Ag), or the like is used as the metal element constituting the first electrode 10. The first electrode 10 or the variable resistance film 11 may include a multinary material that contains multiple elements other than the elements shown above as long as the relationship |ΔG₂|<|ΔG₁| holds for the standard reaction Gibbs energy when comparing one of the constituting elements.

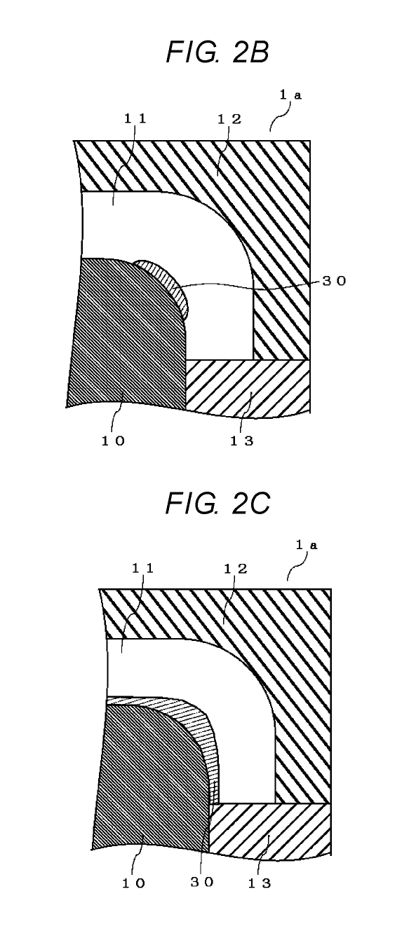

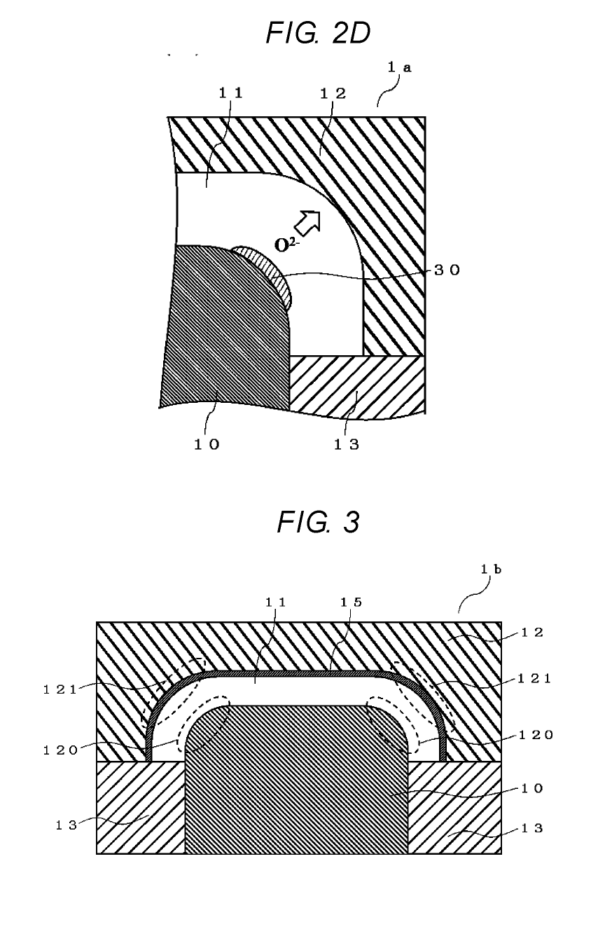

The operation of the semiconductor element 1a is now explained with reference to FIGS. 2A through 2D. FIGS. 2A through 2D are enlarged cross-sectional views illustrating the operation of the semiconductor element 1a according to the first embodiment.

Initially, when an electric field is applied between the first electrode 10 and the second electrode 12, such that the first and second electrodes 10 and 12 become an anode and a cathode, respectively, the electric field is similarly formed through the variable resistance film 11. The electric field applied to the variable resistance film 11 ionizes oxygen atoms in the variable resistance film 11, and then the ionized oxygen atoms diffuse towards the first electrode 10 through an oxygen lacking portion of the variable resistance film 11 as illustrated in FIG. 2A. The oxygen ions (O²⁻) diffuse through the variable resistance film 11 and fill an oxygen lacking portion of the variable resistance film 11 in the vicinity of the first electrode 10. The negative charge formed in the oxygen ions, causes the oxygen ions to flow towards the anode.

The diffusion of the oxygen ions into the oxygen lacking portion of the variable resistance film 11 in the vicinity of the first electrode 10 initially preferentially forms a high resistance layer 30 in the variable resistance film 11 in the vicinity of the convex feature 120, as illustrated in FIG. 2B. The high resistance layer 30 is a layer having a stoichiometric composition of the variable resistance film 11 as a result of the movement of oxygen ions, and therefore has high resistance. When the electric field is continuously applied for a desired period of time to the variable resistance film 11, a high resistance layer 30 is formed across the entire area of the variable resistance film 11 in the vicinity of the first electrode 10 as illustrated in FIG. 2C. This high resistance condition of the semiconductor element 1a is thus produced, where the high resistance layer 30 that is formed across the entire area of the variable resistance film 11 in the vicinity of the first electrode 10, is called a “reset condition”.

On the other hand, when an electric field is applied between the first electrode 10 and the second electrode 12 such that the first and second electrodes 10 and 12 become a cathode and an anode, respectively, the electric field is similarly formed through the high resistance layer 30. The electric field can then produce ionized oxygen in the high resistance layer 30. The oxygen ions in the high resistance layer 30 diffuse toward the second electrode 12 which is the anode. In this case, as noted above, initially the high resistance layer 30 that was preferentially formed on the convex feature 120 has a larger thickness in the vicinity of the convex feature 120. Accordingly, the formed electric field is difficult to concentrate thereon, and the oxygen in the high resistance layer 30 that is distributed across the entire area of the variable resistance layer is preferentially ionized in an area other than the convex feature 120. As a result, the high resistance layer 30 in an area other than the vicinity of the convex feature 120 preferentially disappears, as illustrated in FIG. 2D, and after a desired period of time the semiconductor element 1a finally returns to the condition shown in FIG. 2A, in which the semiconductor element 1a has a low resistance. The low resistance condition of the semiconductor element 1a is called a “set condition”.

Thereafter, the polarities of the first electrode 10 and the second electrode 12 are switched so as to allow the appearance or disappearance of the high resistance layer 30 on the convex feature 120 and thereby alternately repeating the reset condition of the semiconductor element 1a (OFF condition of the semiconductor element 1a) and the set condition of the semiconductor element 1a (ON condition of the semiconductor element 1a), as discussed above. In other words, the semiconductor element 1a alternately repeats the condition shown in FIG. 2C (reset condition) and the condition shown in FIG. 2A (set condition) during its use as a variable resistance memory device.

The advantages offered by the semiconductor element 1a will now be explained. In one embodiment of the semiconductor element 1a, the variable resistance film 11 is provided on the first electrode 10 which is provided with the convex feature 120, while the second electrode 12, which is provided with the concave feature 121 opposed to the convex feature 120, is provided on the variable resistance film 11. In this case, when the electric field is applied to the first electrode 10 and the second electrode 12, the electric field concentrates on the convex feature 120 within the variable resistance film 11. As a result, the high resistance layer 30 is more easily formed in the area of the variable resistance film 11 near the convex feature 120 than in the area of the first electrode 10 not near, or adjacent to, the convex feature 120. In this case, the semiconductor element 1a has a point or a region (area close to the convex feature 120) where the high resistance layer 30 is easily formed. Accordingly, the semiconductor element 1a is allowed to operate by a lower voltage than the voltage required by a structure which uses a first electrode 10 that does not have the convex feature 120. In other words, the operation current of the semiconductor element 1a is smaller than the operation current of a semiconductor element which is not provided with the convex feature 120.

Moreover, the metal element constituting the first electrode 10 and the variable resistance film 11 have the relationship |ΔG₂|<|ΔG₁|. Therefore, the reset condition and the set condition noted above are allowed to be reliably switched over the life of the device.

A modified example of the semiconductor element 1a of the first embodiment is now explained with reference to FIG. 18. FIG. 18 is a cross-sectional view illustrating the structure of a semiconductor element 1f according to the modified example of an embodiment described above.

The point that the semiconductor element 1f is different from the semiconductor element 1a is that an insulation film 15 is provided between the first electrode 10 and the variable resistance film 11. Other structures and operations of the semiconductor element 1f are similar to the corresponding structures and operations of the semiconductor element 1a, and therefore are not repeatedly explained herein.

The semiconductor element 1f is provided with the convex feature 120 similarly to the semiconductor element 1a. This structure decreases the voltage that needs to be applied to the semiconductor element 1f. Moreover, since the insulation film 15 is provided on the surface of the first electrode 10 beforehand, this structure further provides an advantage due to the reduction of the required operation current in the set operating condition. Not intending be limit the scope of disclosure provided herein, in one example, the insulation film 15 may include a stoichiometric metal material that has both relationship of |ΔG_{film15}|<|ΔG_{electrode10}| and |ΔG_{film15}|<|ΔG_{film11}|.

### Second Embodiment

A semiconductor element 1b according to a second embodiment is hereinafter described with reference to FIG. 3. In the description of the second embodiment, points similar to the corresponding points in the first embodiment are not repeatedly explained, and only the points that are different from these configurations are touched upon herein. FIG. 3 is a cross-sectional view illustrating the structure of the semiconductor element 1b according to the second embodiment.

The semiconductor element 1b is generally different from the semiconductor element 1a, since the insulation film 15 is provided between the second electrode 12 and the variable resistance film 11. Assuming that an absolute value of standard reaction Gibbs energy required by an element constituting the insulation film 15 for forming oxide is |ΔG₃|, and |ΔG₃| of the insulation film 15 is selected so that it is larger than |ΔG₁|, which corresponds to the standard reaction Gibbs energy of the variable resistance film 11. Other structures of the second embodiment are similar to the corresponding structures of the first embodiment, and the same explanation is not repeated herein. Similarly, the operation of the semiconductor element 1b is identical to the operation of the semiconductor element 1a, and therefore is not explained herein.

The advantages of the semiconductor element 1b will now be explained. The semiconductor element 1b offers advantages similar to the advantages of the semiconductor element 1a, and further offers other advantages. Discussed herein are the additional advantages provided by the semiconductor element 1b. The insulation film 15 includes insulating material having a band gap larger than the band gap of the variable resistance film 11 and lowering the dielectric constant of the insulating film 15. According to this structure, an electric field is applied to the first electrode 10, such that the first electrode 10 becomes an anode to form the high resistance layer 30 to bring the semiconductor element 1b into the reset condition. Next, an electric field is applied to the first electrode 10 such that the first electrode 10 becomes a cathode to remove the high resistance layer 30 and bring the semiconductor element 1b into the set condition. The presence of the insulating film 15 prevents the formation of the high resistance layer 30 in the vicinity of the second electrode 12 which becomes the anode. In other words, this structure prevents erroneous reset immediately after switching to the set condition.

Moreover, when the semiconductor elements 1b are connected with word lines and bit lines that are used in a semiconductor device, this structure prevents the reverse flow of current caused by the potential differences created between the plural semiconductor elements 1b during operation. In this case, the number of the semiconductor elements 1b connectable to the word lines and bit lines increases, therefore the memory capacity of the semiconductor device can be enlarged.

Furthermore, a semiconductor device including plural semiconductor elements 1b that are connected to the word lines and bit lines, it is not necessary to separately prepare rectifying elements, such as Si diodes, and connect these elements to the semiconductor device in order to obtain the foregoing advantages. Accordingly, the manufacturing cost of the semiconductor device decreases by eliminating the need for the steps required to produce the rectifying elements.

### Third Embodiment

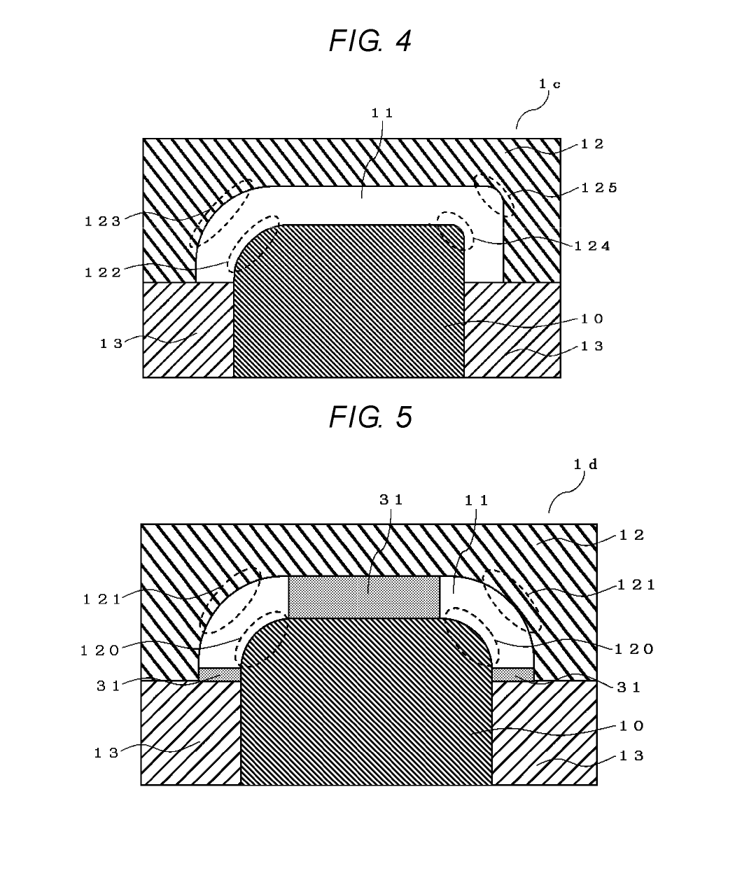

A semiconductor element 1c according to a third embodiment is hereinafter described with reference to FIG. 4. In the description of the third embodiment, points similar to the corresponding points in the first embodiment are not explained again herein, and only the points that are different from these configurations are touched upon herein. FIG. 4 is a cross-sectional view illustrating the structure of the semiconductor element 1c according to the third embodiment.

The semiconductor element 1c is different from the semiconductor element 1a, since the semiconductor element 1c includes a first convex feature 122 and a second convex feature 124 that each have a different curvature, and a first concave feature 123 and a second concave feature 125 each have a different curvature as discussed herein. The first convex feature 122 and the second convex feature 124 are disposed on the first electrode 10, whereas the first concave feature 123 and the second concave feature 125 are disposed on the second electrode 12. Other structures of the third embodiment are similar to the corresponding structures of the first embodiment, and thus are not repeated herein. Similarly, the operation of the semiconductor element 1c is identical to the operation of the semiconductor element 1a, and therefore is not explained herein.

The advantages of the semiconductor element 1c will now be explained. The semiconductor element 1c offers advantages similar to the advantages of the semiconductor element 1a, and further offers additional advantages. Discussed herein are the additional advantages provided by the semiconductor element 1c. The semiconductor element 1c which includes the first convex feature 122 and the second convex feature 124 having different curvatures, and the first concave feature 123 and the second concave feature 125 having different curvatures will provide a memory element that has three different resistance levels or higher. More specifically, when the curvatures of the first convex feature 122 and the second convex feature 124 are different, the speed at which the high resistance layer 30 is formed on the first convex feature 122 within the variable resistance film 11 when a voltage is applied to the first electrode 10 and the second electrode 12 is different from the speed at which the high resistance layer 30 is formed on the second convex feature 124. Accordingly, the semiconductor element 1c provides a memory element that has three or more resistance levels as noted above, thereby allowing multi-value variable resistance memory operation.

While not intending to be bound by theory, it is believed that the generated electric field concentrates on a sharp convex feature. Therefore, the high resistant layer 30 forms on sharply curved feature at low voltage and forms on less sharply curved feature at higher voltage. Therefore, this curvature difference can change resistance memory operation voltage.

### Fourth Embodiment

A semiconductor element 1d according to a fourth embodiment is hereinafter described with reference to FIG. 5. In the description of the fourth embodiment, points similar to the corresponding points in the embodiments described above are not explained again herein, and only the points that are different between these configurations are touched upon herein. FIG. 5 is a cross-sectional view illustrating the structure of the semiconductor element 1d according to an embodiment.

The semiconductor element 1d is different from the semiconductor element 1a, since the semiconductor element 1d includes a high oxygen concentration variable resistance film 31 that is partially provided within the variable resistance film 11. The high oxygen concentration variable resistance film 31 may be formed in any positions within the variable resistance film 11. In some configurations, the high oxygen concentration variable resistance film 31 can be disposed in the area of the variable resistance film 11 not opposed to the convex feature 120. Other structures of the fourth embodiment are similar to the corresponding structures of the first embodiment, and the same explanation is not repeated herein. Similarly, the operation of the semiconductor element 1d is identical to the operation of the semiconductor element 1a, and therefore is not explained herein.

The advantages of the semiconductor element 1d will now be explained. The semiconductor element 1d offers advantages similar to the advantages of the semiconductor element 1a, and further offers other additional advantages. Discussed herein are the additional advantages provided by the semiconductor element 1d. To assure that a high resistance layer 30 is formed across the variable resistance film 11, which contacts the whole first electrode 10, during the reset operation, a high-voltage bias or long-term bias usually needs to be applied to the first electrode 10. When a long-term or high-voltage bias is applied to the first electrode 10, such a condition may reduce the memory operation speed and/or may prevent the memory device scaling. On the other hand, when the formation of the high resistance layer 30 is insufficient, a leakage current is generated during the reset condition of the semiconductor element. In this case, the problem of larger power consumption arises as more memory devices are integrated together in the semiconductor element.

According to this embodiment, a high oxygen concentration variable resistance film 31, which is easily oxidized, is provided within at least one part of the variable resistance film 11 of the semiconductor element 1d. In this case, the high oxygen concentration variable resistance film 31 is easily changed to a high resistance layer 30 (not shown) during the reset condition. As discussed above, when a positive bias is applied to the first electrode 10, the electric field concentrates on the area close to the convex feature 120 of the first electrode 10 to promote the formation of the high resistance layer 30 (not shown). Moreover, the high oxygen concentration variable resistance film 31 is easily oxidized (i.e., easily forms a high resistance layer 30 therein) is provided within the variable resistance film 11 in an area other than the position of the convex feature 120. In this case, the semiconductor element 1d is easily brought into the reset condition. Accordingly, the operation voltage of the semiconductor element 1d decreases, therefore the power consumption is lowered. Furthermore, the high resistance layer 30 is easily formed on the surface of the first electrode 10 of the semiconductor element 1d, therefore the leakage current is decreased in the reset condition for a semiconductor element 1d versus another semiconductor elements that do not contain the high oxygen concentration variable resistance film 31.

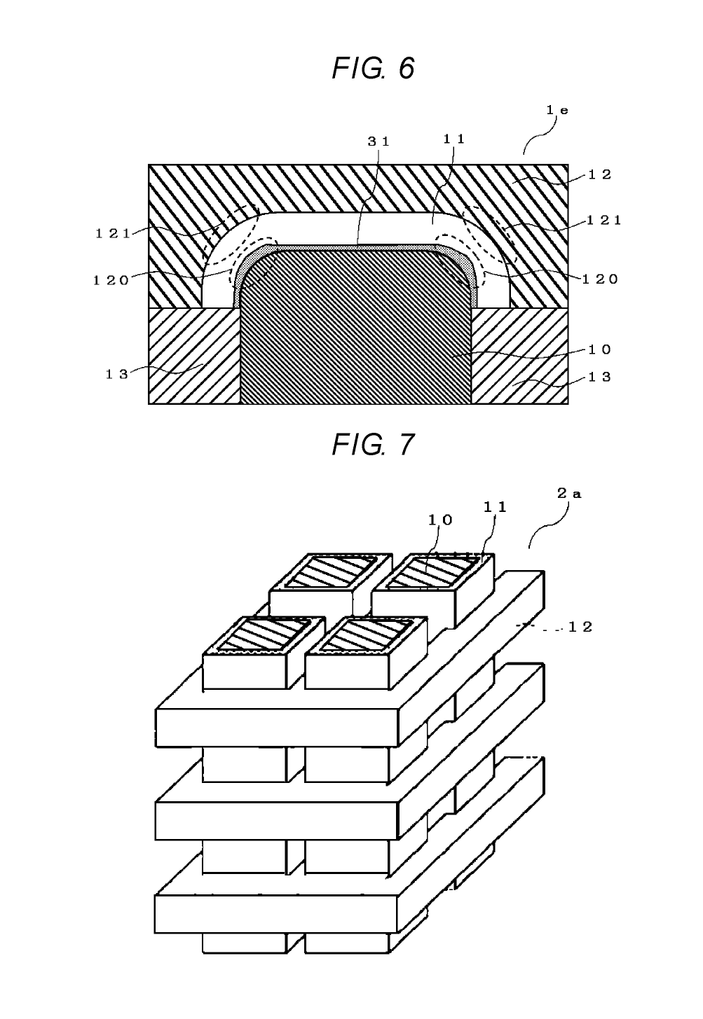

A semiconductor element 1e according to a modified example of the fourth embodiment is hereinafter described with reference to FIG. 6. In the description of this modified example, points that are similar to the corresponding points in the embodiments described above are not explained again herein, and only the points that are different between these configurations are touched upon herein. FIG. 6 is a cross-sectional view illustrating the structure of the semiconductor element 1e according to a modified example of the one or more of the embodiments described above.

The semiconductor element 1e is different from the semiconductor element 1d in that the high oxygen concentration variable resistance film 31 is provided on the entire surface of the first electrode 10. The other parts of semiconductor element 1e structure are similar to the corresponding structures discussed above, and the same explanation is thus not repeated herein.

In one embodiment of the semiconductor element 1e, the high oxygen concentration variable resistance film 31 is similarly provided within the variable resistance film 11. This structure provides the advantage of secure formation of the high resistance layer 30 when the semiconductor element 1e is brought into the reset condition. In FIG. 6, the high oxygen concentration variable resistance film 31 within the variable resistance film 11 in an area that is opposed to the convex feature 120 has a greater thickness than the thickness of the high oxygen concentration variable resistance film 31 in an area other than the area opposed to the convex feature 120. In this case, the operation for bringing the semiconductor element 1e into the set condition is initially executed.

Moreover, similar to the semiconductor element 1d, the semiconductor element 1e easily forms the high resistance layer 30 across the surface of the first electrode 10. Thus, the semiconductor element 1e further provides the advantage of reducing the leak current in the reset condition.

According to this embodiment, the structure which provides the high oxygen concentration variable resistance film 31 within the variable resistance film 11 is discussed. However, similar advantages are offered by a structure which provides a gradient in the oxygen concentration within the variable resistance film 11. In this case, it is preferable that the oxygen concentration of the variable resistance film 11 increases in a direction extending from the second electrode 12 to the first electrode 10.

### Fifth Embodiment

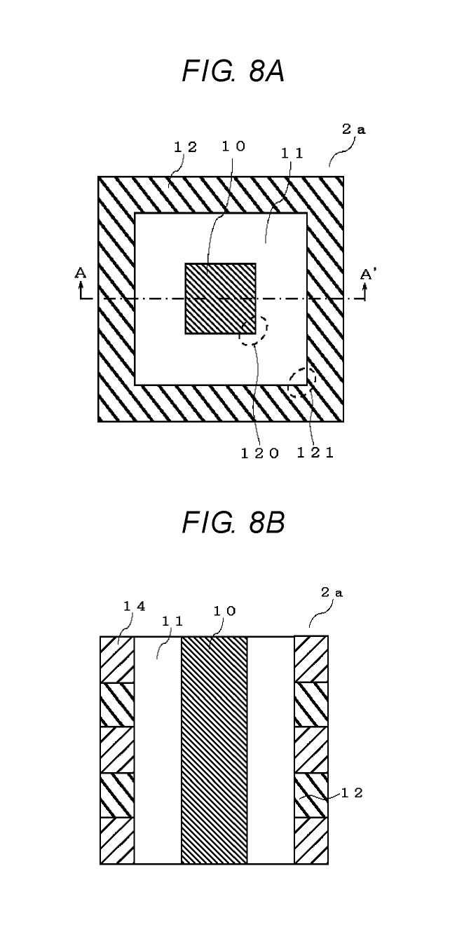

A semiconductor device 2a according to a fifth embodiment is hereinafter described with reference to FIGS. 7 and 8A and 8B. FIG. 7 is an isometric view illustrating the structure of the semiconductor device 2a according to the fifth embodiment. FIG. 8A is a plan cross-sectional view illustrating the structure of the semiconductor device 2a according to an embodiment. FIG. 8B is a cross-sectional view taken along a line A-A′ in FIG. 8A.

As illustrated in FIG. 7, the semiconductor device 2a has a three-dimensional structure which generally includes the plural first electrodes 10, the plural second electrodes 12, and inter-electrode insulation films 14 (not shown). The first electrodes 10 extend in the direction perpendicular to the plural second electrodes 12 and the interelectrode insulation films 14 (not shown) may alternately extend in the horizontal direction. The convex feature 120 is provided on each side surface of the first electrodes 10, while the concave feature 121 opposed to the corresponding convex feature 120 is provided on each side surface of the second electrodes 12.

As illustrated in FIGS. 8A and 8B, the variable resistance film 11 is provided on each side surface of the first electrodes 10. In other words, the semiconductor device 2a has a structure including the plural semiconductor elements la according to the first embodiment in the direction perpendicular to the first electrodes 10. The first electrodes 10 and the second electrodes 12 are connected with word lines and bit lines, respectively, to allow operation of the semiconductor device 2a.

It is assumed herein that an absolute value of standard reaction Gibbs energy of a metal element constituting the variable resistance film 11 is |ΔG₁|, and that an absolute value of standard reaction Gibbs energy of a metal element constituting the first electrode 10 is |ΔG₂|. According to the semiconductor device 2a in this embodiment, the materials of the variable resistance film 11 and the first electrode 10 are selected such that the relationship |ΔG₂|<|ΔG₁| holds. In other words, the metal element constituting the first electrode 10 and the metal element constituting the variable resistance film 11 have the relationship |ΔG₂|<|ΔG₁|. The semiconductor device 2a disclosed herein is a device constructed similar to the devices described above.

In order to satisfy the relationship |ΔG₂|<|ΔG₁| between the first electrode 10 and the variable resistance film 11, titanium (Ti), silicone (Si), vanadium (V), tantalum (Ta), manganese (Mn), niobium (Nb), chromium (Cr), tungsten (W), molybdenum (Mo), iron (Fe), or the like is used as the metal element constituting the variable resistance film 11. On the other hand, in order to satisfy the relationship |ΔG₂|<|ΔG₁| for the standard reaction Gibbs energy, aluminum (Al), Ti, Si, Ta, Mn, Nb, Cr, W, Mo, Fe, cobalt (Co), nickel (Ni), rhenium (Re), copper (Cu), ruthenium (Ru), cerium (Ce), iridium (Ir), palladium (Pd), silver (Ag), or the like is used as the metal element constituting the first electrode 10. The first electrode 10 or the variable resistance film 11 may include a multinary material that contains multiple elements other than the elements shown above, as long as the relationship |ΔG₂|<|ΔG₁| holds for the standard reaction Gibbs energy when comparing one of the constituting elements.

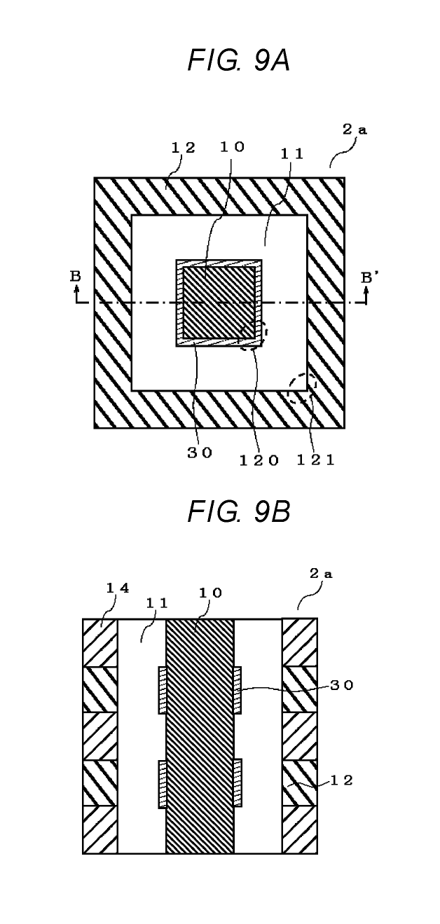

The operation of the semiconductor device 2a is now explained with reference to FIGS. 8A through 9B. FIG. 9A is a plan view illustrating the structure of the semiconductor device 2a in the reset condition according to the fifth embodiment, while FIG. 9B is a cross-sectional view illustrating a cross section in the reset condition taken along a line B-B′ in FIG, 9A.

Initially, when an electric field is applied between the first electrode 10 and the second electrode 12, such that the first and second electrodes 10 and 12 become an anode and a cathode, respectively, an electric field is formed through the variable resistance film 11. The electric field applied to the variable resistance film 11 ionizes oxygen atoms in the variable resistance film 11, and then the ionized oxygen diffuses towards the first electrode 10 through an oxygen lacking portion of the variable resistance film 11. The oxygen ions (O²⁻) diffuse through the variable resistance film 11 and fill an oxygen lacking portion of the variable resistance film 11 in the vicinity of the first electrode 10. The negative charge formed in the oxygen ions, causes the oxygen ions to flow towards the anode.

The diffusion of the oxygen ions into the oxygen lacking portion of the variable resistance film 11 in the vicinity of the first electrode 10 forms a high resistance layer 30 in the variable resistance film 11 that contacts the first electrode 10, as illustrated in FIGS. 9A and 9B. The high resistance layer 30 may form a layer in the variable resistance film 11 that has a stoichiometric composition as a result of the diffusion of the oxygen ions, and therefore has high resistance. In this case, the electric field concentrates on the convex feature 120, therefore the high resistance layer 30 is formed on the convex feature 120 in preference to the surface of the first electrode 10 that does not contain the convex feature 120. When the electric field is continuously applied for a desired period of time to the variable resistance film 11, the high resistance layer 30 will form across the area of the variable resistance film 11 in the vicinity of the first electrode 10, as shown in FIGS. 9A and 9B. As a result, the semiconductor device 2a is brought into a reset condition.

On the other hand, when an electric field is applied between the first electrode 10 and the second electrode 12 such that the first and second electrodes 10 and 12 become a cathode and an anode, respectively, the electric field is similarly applied to the high resistance layer 30. The applied electric field thus ionizes oxygen in the high resistance layer 30. The oxygen ions in the high resistance layer 30 then diffuse towards the second electrode 12 which is the anode. In general, the outer circumferential area of the first electrode 10 (contact area between the variable resistance film 11 and the first electrode 10) is smaller than the inner circumferential area of the second electrode 12 (contact area between the variable resistance film 11 and the second electrode 12). In this case, the electric field readily concentrates on the first electrode 10, and the oxygen in the high resistance layer 30 is preferentially ionized on the surface of the first electrode 10. As a result, the high resistance layer 30 in the area in the vicinity of the convex feature 120 preferentially disappears, and then the high resistance layer 30 completely disappears in the final stages of this process as illustrated in FIGS. 8A and 8B when biased this way. Consequently, the semiconductor device 2a comes into the low resistance condition, and therefore reaches the set condition.

Thereafter, the polarities of the first electrode 10 and the second electrode 12 can be switched to allow the appearance or disappearance of the high resistance layer 30 and thus allow the reset condition and the set condition of the semiconductor element 2a to be performed as discussed above. FIGS. 9A and 9B show an example which forms the high resistance layers 30 on the surfaces of all the first electrodes 10, which are opposed to the second electrodes 12, during a reset operating condition. However, the structure according to this embodiment is capable of individually applying voltages to the respective second electrodes 12, therefore formation of the high resistance layer 30 is not necessarily required on the surfaces of all the first electrodes 10 for practicing this embodiment.

The advantages offered by the semiconductor device 2a are now explained. The variable resistance film 11 is provided on the side surface of the first electrode 10, which is provided with the convex feature 120. The second electrode 12 which has the concave feature 121 is opposed to the convex feature 120 and is provided on the variable resistance film 11 so that the second electrode 12 and the variable resistance film 11 are in electrical contact. According to this structure, an electric field applied to the first electrode 10 and the second electrode 12 concentrates on the convex feature 120 within the variable resistance film 11. As a result, the high resistance layer 30 is more easily formed in the area of the variable resistance film 11 opposed to the convex feature 120 than in the area of the variable resistance film 11 not opposed to the convex feature 120. In this case, the semiconductor device 2a has a point or region (area close to the convex feature 120) where the high resistance layer 30 is easily formed. Accordingly, the semiconductor device 2a operates by a lower voltage than the applied voltage required by a structure which uses the first electrode 10 not provided with the convex feature 120. In other words, the operation current of the semiconductor device 2a is smaller than the operation current of a semiconductor device, which is not provided with the convex feature 120.

Moreover, the metal element constituting the first electrode 10 and the metal element constituting the variable resistance film 11 have the relationship |ΔG₂|<|ΔG₁|. Therefore, switching between the reset condition and the set condition as noted above can be maintained.

### Sixth Embodiment

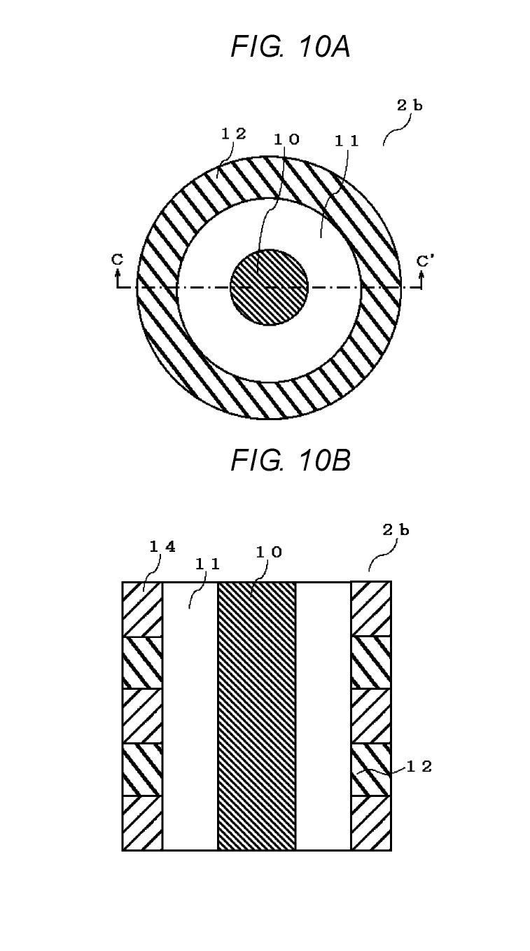

The structure of a semiconductor device 2b according to a sixth embodiment is hereinafter described with reference to FIGS. 10A and 10B. FIG. 10A is a plan view illustrating the structure of the semiconductor device 2b according to an embodiment, while FIG. 10B is a cross-sectional view showing a cross section taken along a line C-C′ in FIG. 10A.

The semiconductor device 2b is different from the semiconductor device 2a in that the cross sections of the first electrode 10 and the variable resistance film 11 extending in the vertical direction are concentric. Other structures in this configuration are similar to the corresponding structures in the other embodiments described above, and the same explanation is not repeated herein.

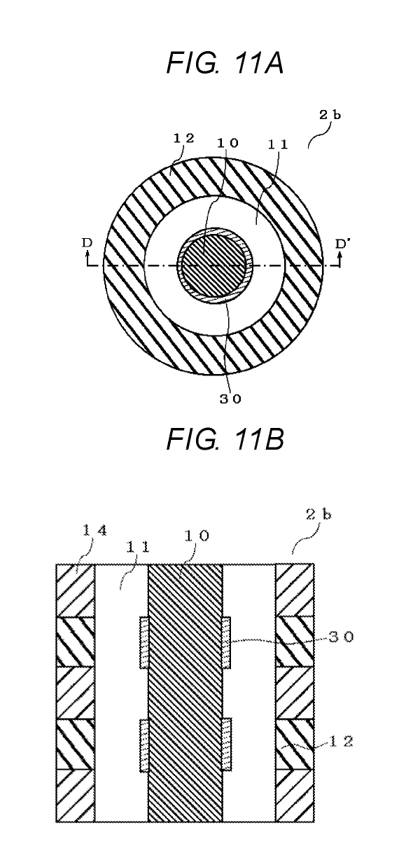

The operation of the semiconductor device 2b is now explained with reference to FIGS. 11A and 11B. FIG. 11A is a plan view illustrating the structure of the semiconductor device 2b in the reset condition, while FIG. 11B is a cross-sectional view illustrating across section in the reset condition taken along a line D-D′ in FIG. 11A.

When an electric field is applied between the first electric field 10 and the second electrode 12, such that the first and second electrodes 10 and 12 serve as an anode and a cathode, respectively, during the operation of the semiconductor device 2b, the electric field is applied to the variable resistance film 11, as similarly described above in relation to the operation of the semiconductor device 2a. As a result, a high resistance layer 30 is formed within the variable resistance film 11 in the vicinity of the first electrode 10 as illustrated in FIGS. 11A and 11B, therefore the semiconductor device 2b comes into the reset condition.

On the other hand, when an electric field is applied between the first electrode 10 and the second electrode 12 such that the first and second electrodes 10 and 12 become a cathode and an anode, respectively, the electric field is applied to the high resistance layer 30. As a result, the high resistance layer 30 disappears. In other words, the semiconductor device 2b comes into the condition shown in FIGS. 10A and 10B, i.e., the set condition.

Thereafter, the polarities of the first electrode 10 and the second electrode 12 are switched to alternately repeat the reset condition and the set condition of the semiconductor device 2b during the operation of the semiconductor device.

The advantages offered by the semiconductor device 2b are now explained. The outer circumferential area of the first electrode 10 (contact area between the variable resistance film 11 and the first electrode 10) is smaller than the inner circumferential area of the second electrode 12 (contact area between the variable resistance film 11 and the second electrode 12) in the semiconductor device 2b relative to the same structure in the semiconductor device 2a. In this case, the electric field easily concentrates on the first electrode 10, therefore oxygen atoms in the high resistance layer 30 are preferentially ionized on the surface of the first electrode 10. Accordingly, appearance and disappearance of the high resistance layer 30 become easier, therefore the power consumption of the semiconductor device 2b is similarly decreased.

Furthermore, when the cross-sectional shape of the first electrode 10 extending in the vertical direction is concentric, the area of the first electrode 10 contacting the resistance variable film 11 becomes smaller than that area of the first electrode 10 having a rectangular cross section. In other words, the area forming the high resistance layer 30 substantially decreases. Accordingly, the power consumption of the semiconductor device 2b decreases, and the semiconductor device 2b can be reliably brought into the reset condition.

In addition, similarly to the case of the semiconductor device 2a, the metal element constituting the first electrode 10 and the metal element constituting the variable resistance film 11 have the relationship |ΔG₂|<|ΔG₁|. Accordingly, the operation for switching between the reset condition and the set condition noted above can be maintained.

### Seventh Embodiment

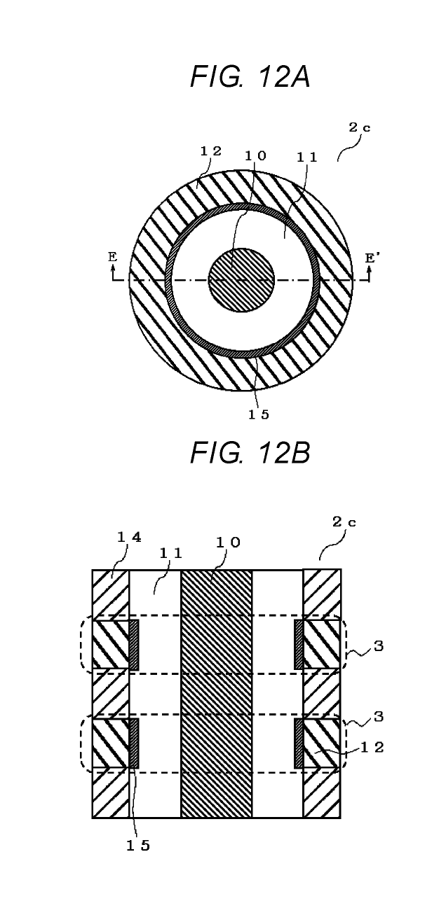

The structure of a semiconductor device 2c according to a seventh embodiment is hereinafter described with reference to FIGS. 12A and 12B. FIG. 12A is a plan view illustrating the structure of the semiconductor device 2c according to an embodiment, while FIG. 12B is a cross-sectional view showing a cross section taken along a line E-E′ in FIG. 12A.

The semiconductor device 2c is different from the semiconductor device 2b in that the insulation film 15 is provided between the second electrode 12 and the variable resistance film 11, as illustrated in FIGS. 12A and 12B. Assuming herein that an absolute value of standard reaction Gibbs energy required by an element constituting the insulation film 15 for forming oxide is |ΔG₃|, the value |ΔG₃| is set larger than the value |ΔG₁| corresponding to the standard reaction Gibbs energy of the variable resistance film 11. According to this embodiment, the insulation film 15 shown in the figures is provided between the variable resistance film 11 and the second electrode 12 opposed to the first electrode 10. However, the insulation film 15 may be provided over the entire surface between the first electrode 10 and both the second electrode 12 and the interelectrode insulation film 14.

Other structures in this configuration are similar to the corresponding structures in the embodiments described above, and the same explanation is thus not repeated herein. In addition, the operation of the semiconductor device 2c is identical to the operation of the semiconductor device 2b, and therefore is not explained herein.

The advantages of the semiconductor device 2c are now explained. The semiconductor device 2c offers advantages similar to the advantages of the semiconductor device 2b, and further offers other advantages. Discussed herein are the additional advantages provided by the semiconductor device 2c. The insulation film 15 includes insulating material having a band gap larger than the band gap of the variable resistance film 11 and lowering the dielectric constant of the insulation film 15. According to this structure, an electric field is applied to the first electrode 10 such that the first electrode 10 becomes an anode to form the high resistance layer 30 thereon and thus bringing the semiconductor device 2c into the reset condition. Thereafter, an electric field is applied to the first electrode 10 such that the first electrode 10 becomes a cathode to remove the high resistance layer 30 and thus bringing the semiconductor device 2c into the set condition. In the stage of the set condition, this structure prevents formation of the high resistance layer 30 in the vicinity of the second electrode 12, which is the anode. In other words, this structure avoids an erroneous reset condition immediately after switching to the set condition.

Moreover, this structure prevents reverse flow of current caused by the potential difference between plural semiconductor elements 3 shown in FIG. 12B. Accordingly, the number of the semiconductor elements 3 contained in the semiconductor device 2c increases, therefore the storage capacity of the semiconductor device 2c is increased.

Furthermore, in the manufacture of the semiconductor device 2c, it is not necessary to separately prepare rectifying elements such as Si diodes and connect the elements to the semiconductor device 2c in order to obtain the foregoing advantages. Accordingly, the manufacturing cost of the semiconductor device 2c decreases by eliminating the need for the steps required to form the rectifying elements.

### Eighth Embodiment

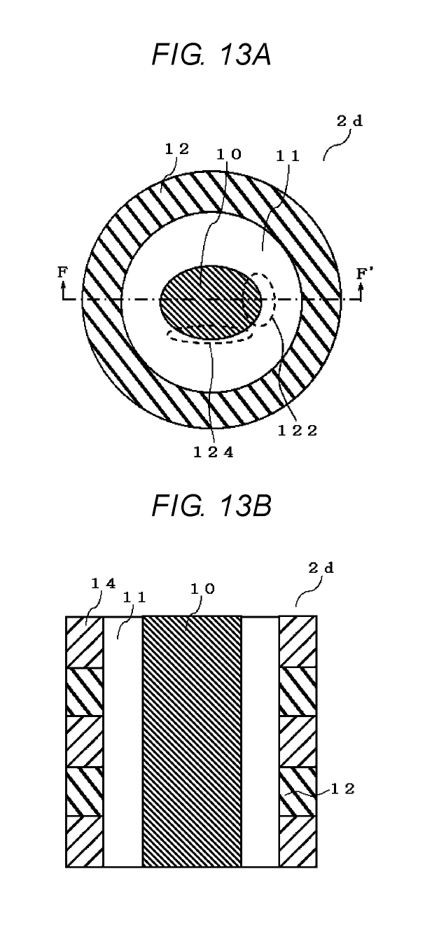

The structure of a semiconductor device 2d according to an eighth embodiment is hereinafter described with reference to FIGS. 13A and 13B. FIG. 13A is a plan view illustrating the structure of the semiconductor device 2d according to an embodiment, while FIG. 13B is a cross-sectional view showing a cross section taken along a line F-F′ in FIG. 13A.

The semiconductor element 2d according to an embodiment is hereinafter described with reference to FIGS. 13A and 13B. In the description of this configuration, points similar to the corresponding points in the other embodiments described above are not explained again, and only the differences are touched upon herein. FIG. 13A is a plan view illustrating the structure of the semiconductor device 2d, while FIG. 13B is a cross-sectional view illustrating a cross section taken along a line F-F′ in FIG. 13A.

The semiconductor device 2d is different from the semiconductor device 2b in that the first electrode 10 includes the first convex feature 122 and the second convex feature 124 having different curvatures. Other structures in the eighth embodiment are similar to the corresponding structures in the other embodiments described above, and the same explanation is not repeated herein. Similarly, the operation of the semiconductor device 2d is identical to the operation of the semiconductor device 2b, and the same explanation is not repeated herein.

The advantages of the semiconductor device 2d are now explained. The semiconductor device 2d offers advantages similar to the advantages of the semiconductor device 2b, and further offers other advantages. Discussed herein are the additional advantages provided by the semiconductor device 2d. The semiconductor device 2d which is provided with the first convex feature 122 and the second convex feature 124 having different curvatures can provide a memory element that has three resistance of levels or higher. More specifically, when the curvatures of the first convex feature 122 and the second convex feature 124 are different, the speed at which the high resistance layer 30 is formed on the first convex feature 122 within the variable resistance film 11 when a voltage is applied to the first electrode 10 and the second electrode 12 is different from the speed at which the high resistance layer 30 is formed on the second convex feature 124. Accordingly, the semiconductor device 2d provides a memory element that has three resistance levels or higher as noted above, thereby allowing multi-value operation.

### Ninth Embodiment

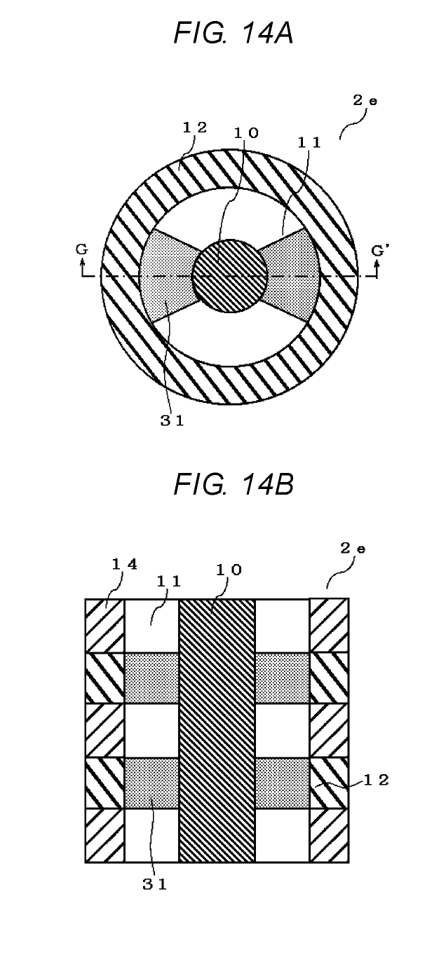

A semiconductor device 2e according to a ninth embodiment is hereinafter described with reference to FIGS. 14A and 14B. In the description of this configuration, points that are similar to the corresponding points in the other embodiments described above are not explained again, and only the differences are touched upon herein. FIG. 14A is a plan view illustrating the structure of the semiconductor device 2e, while FIG. 14B is a cross-sectional view illustrating a cross section taken along a line G-G′ in FIG. 14A.

The semiconductor device 2e is different from the semiconductor device 2b in that a high oxygen concentration variable resistance film 31 is partially provided within the variable resistance film 11. Other structures in this configuration are similar to the corresponding structures in the embodiments described above, and the same explanation is thus not repeated again. Similarly, the operation of the semiconductor device 2e is identical to the operation of the semiconductor device 2b, and the same explanation is thus not repeated again.

The advantages of the semiconductor device 2e are now explained. The semiconductor device 2e offers advantages similar to the advantages of the semiconductor device 2b, and further offers other advantages. Discussed herein are the additional advantages provided by the semiconductor device 2e. To assure that a high resistance layer 30 is formed across the entire area of the variable resistance film 11 during the reset operation, it is typically necessary to apply a high-voltage bias or long-term bias to the first electrode 10. When a long-term or high-voltage bias is applied to the first electrode 10, such a condition maybe produced that lowers the memory operation speed of the semiconductor device. On the other hand, when formation of the high resistance layer 30 is insufficient, a leakage current is generated during the reset operation performed on the semiconductor device. In this case, the problem of larger power consumption of the semiconductor device arises as more memory devices are integrated together in the semiconductor device.

According to this embodiment, a high oxygen concentration variable resistance film 31, which is easily oxidized is provided within at least one part of the variable resistance film 11 of the semiconductor device 2e. In this case, the high oxygen concentration variable resistance film 31 is easily changed to a high resistance layer 30 (not shown) during the reset condition. In other words, the semiconductor device 2e is easily brought into the reset condition. Accordingly, the operation voltage, and therefore the operation power of the semiconductor device 2e decrease. Furthermore, formation of the high resistance layer 30 is facilitated, therefore reducing the leak current in the reset condition.

According to this embodiment, the structure which provides the high oxygen concentration variable resistance film 31 within the variable resistance film 11 is discussed. However, similar advantages are offered by a structure which has a gradient in the oxygen concentration within the variable resistance film 11. In this case, it is preferable that the oxygen concentration of the variable resistance film 11 increase in a direction extending from the second electrode 12 to the first electrode 10, for example, in view of formation of the high resistance layer 30 in the variable resistance film 11 in the vicinity of the first electrode 10.

### Tenth Embodiment

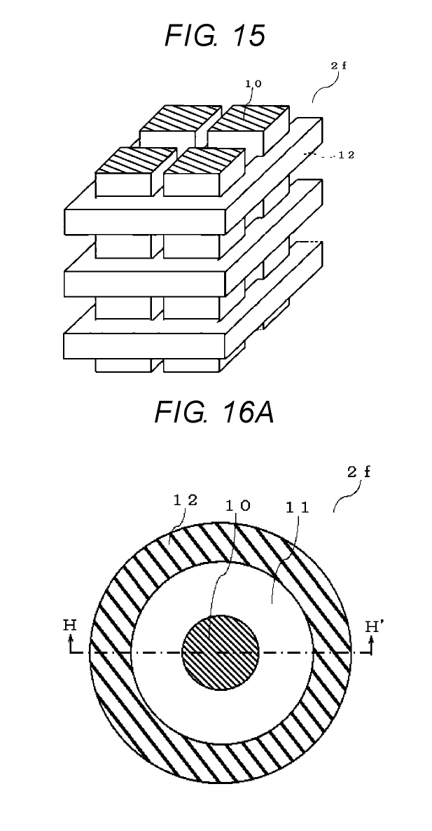

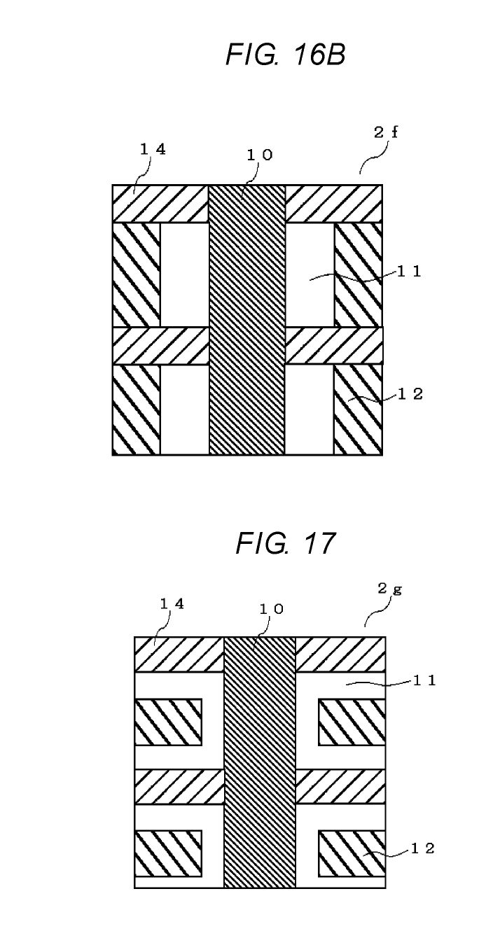

A semiconductor device 2f according to a tenth embodiment is hereinafter described with reference to FIG. 15 and FIGS. 16A and 16B. In the description of this configuration, points that are similar to the corresponding points described in the embodiments discussed above are not explained again, and only the differences are touched upon. FIG. 15 is an isometric view illustrating the structure of the semiconductor device 2f according to an embodiment. FIG. 16A is a plan view illustrating the structure of the semiconductor device 2f according to an embodiment. FIG. 16B is a cross-sectional view illustrating a cross section taken along a line H-H′ in FIG. 16A.

As illustrated in FIG. 15, the semiconductor device 2f has a three-dimensional structure which includes the plural first electrodes 10, the plural second electrodes 12, and the interelectrode insulation films 14 (not shown). The first electrodes 10 extend in the direction perpendicular to the plural second electrodes 12 and the interelectrode insulation films 14 alternately may extend in the horizontal direction.

As illustrated in FIGS. 16A and 16B, the cross-sectional shape of the first electrode 10 extending in the horizontal direction is concentric. The variable resistance film 11 is partially provided on the side surface of the first electrode in such a manner as to be sandwiched between the interelectrode films 14 in the vertical direction. In this case, the variable resistance film 11 of the semiconductor device 2f is provided only between the first electrode 10 and the second electrode 12. The first electrode 10 and the second electrode 12 are connected to a word line and a bit line, respectively, to allow operation of the semiconductor device 2f. Other structures of the semiconductor device 2f are similar to the corresponding structures of the semiconductor device 2b, and the same explanation is not repeated herein. Similarly, the operation of the semiconductor device 2f is identical to the operation of the semiconductor device 2b, and therefore is not explained herein.

The advantages of the semiconductor device 2f are now explained. The semiconductor device 2f offers advantages similar to the advantages of the semiconductor device 2b, and further offers other advantages. Discussed herein are the additional advantages provided by the semiconductor device 2f. As noted above, the variable resistance film 11 of the semiconductor device 2f is provided only between the first electrode 10 and the second electrode 12. In this case, the high resistance layer 30 formed between the first electrode 10 and the variable resistance film 11 under the reset condition extends throughout the area between the first electrode 10 and the second electrode 12. Accordingly, leak current generated in the semiconductor device 2f in the reset condition is reduced, therefore malfunction caused by faulty reset is avoided.

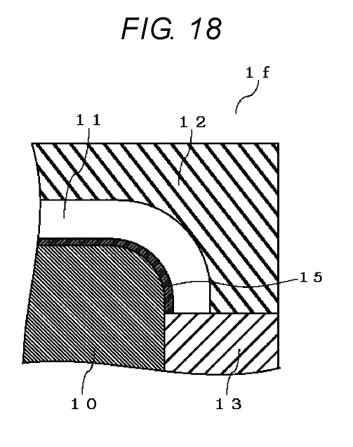

A semiconductor device 2g according to a modified example of the tenth embodiment is hereinafter described with reference to FIG. 17. In the description of this modified example, points similar to the corresponding points in the semiconductor device 2f according to the tenth embodiment are not repeatedly explained, and only different points are touched upon. FIG. 17 is a cross-sectional view illustrating a cross section of the semiconductor device 2g according to the modified example of the tenth embodiment.

The point that the semiconductor device 2g is different from the semiconductor device 2f is that the variable resistance film 11 is provided not only between the first electrode 10 and the second electrode 12 but also between the interelectrode insulation film 14 and the second electrode 12 as illustrated in FIG. 17. Other structures are similar to the corresponding structures discussed above, and the same explanation is not repeated herein.

According to the semiconductor device 2g, leak current generated in the semiconductor device 2g in the reset condition is reduced, therefore malfunction caused by faulty reset is avoided as similarly described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

1. A semiconductor element, comprising:
a first electrode including at least one convex feature;
a second electrode including a concave feature opposed to the convex feature;
a variable resistance layer including an element whose absolute value of standard reaction Gibbs energy for forming an oxide is larger than the corresponding absolute value of standard reaction Gibbs energy for forming an oxide by an element included in the first electrode, wherein the variable resistance layer is disposed between the convex feature and the concave feature; and
an insulator between the second electrode and the variable resistance layer, wherein
the absolute value of standard reaction Gibbs energy required by an element included in the insulator for forming an oxide is larger than the absolute value of standard reaction Gibbs energy for forming an oxide required by the element included in the variable resistance layer.

2. The semiconductor element according to claim 1, wherein
the first electrode comprises at least one of elements selected from a group consisting of Al, Ti, Si, Ta, Mn, Nb, Cr, W, Mo, Fe, Co, Ni, Re, Cu, Ru, Ce, Ir, Pd, and Ag, and
the variable resistance layer substantially comprises an oxide of at least one of elements selected from a group consisting of Ti, Si, V, Ta, Mn, Nb, Cr, W, Mo, and Fe.

3. (canceled)

4. The semiconductor element of claim 1, wherein the at least one convex feature further comprises a plurality of convex features that each have a different curvature.

5. The semiconductor element of claim 1, further comprising a high oxygen concentration variable resistance layer disposed within the variable resistance layer, and having a larger oxygen concentration than an oxygen concentration of the variable resistance layer.

6. The semiconductor element of claim 1, wherein an oxygen concentration of the variable resistance layer increases in the direction extending from the second electrode to the first electrode.

7. The semiconductor element of claim 1, further comprising an insulation layer disposed between the first electrode and the variable resistance layer.

8. A semiconductor device, comprising:
a first electrode extending in first direction and including a convex feature;
a second electrode disposed over a portion of the first electrode, and including a concave feature opposed to the convex feature; and
a variable resistance layer including an element whose absolute value of standard reaction Gibbs energy for forming an oxide is larger than the corresponding value of standard reaction Gibbs energy for forming an oxide of an element included in the first electrode, wherein the variable resistance layer is disposed on the outer circumference of the first electrode and between the first and second electrodes.

9. The semiconductor device of claim 8, wherein
the first electrode comprises at least one element selected from the group consisting of Al, Ti, Si, Ta, Mn, Nb, Cr, W, Mo, Fe, Co, Ni, Re, Cu, Ru, Ce, Ir, Pd, and Ag, and
the variable resistance layer substantially comprises an oxide of at least one element selected from the group consisting of Ti, Si, V, Ta, Mn, Nb, Cr, W, Mo, and Fe.

10. The semiconductor device of claim 8, wherein
an insulator is provided between the second electrode and the variable resistance layer, and
the absolute value of standard reaction Gibbs energy required by an element included in the insulator for forming an oxide is larger than the absolute value of standard reaction Gibbs energy required to form an oxide with an element included in the variable resistance layer.

11. The semiconductor device of claim 8, wherein the first electrode further comprises a plurality of convex features that each have different curvatures.

12. The semiconductor device of claim 8, further comprising a high oxygen concentration variable resistance layer disposed within the variable resistance layer and having a larger oxygen concentration than an oxygen concentration of the variable resistance layer.

13. The semiconductor device of claim 8, wherein an oxygen concentration of the variable resistance layer increases in a direction extending from the second electrode to the first electrode.

14. The semiconductor device of claim 8, wherein the variable resistance layer is disposed only between the first electrode and the second electrode.

15. The semiconductor device of claim 8, further comprising:
a plurality of second electrodes; and
an interelectrode insulation layer that is disposed between the second electrodes, wherein
the variable resistance layer is also provided between the second electrode and the interelectrode insulation layer.

16. A method of forming a semiconductor device, comprising:
forming a first electrode that has a surface that has at least one convex feature formed thereon, wherein the first electrode comprises a first element;
forming a variable resistance layer over the surface of the first electrode, wherein the variable resistance layer comprises a second element whose absolute value of standard reaction Gibbs energy for forming an oxide is larger than the corresponding absolute value of standard reaction Gibbs energy for forming an oxide by the first element included in the first electrode;
forming a second electrode over at least a portion of the variable resistance layer that is disposed over the at least one convex feature formed on the first electrode; and
forming an insulator layer on the variable resistance layer, wherein
the absolute value of standard reaction Gibbs energy required by a third element included in the insulator layer for forming an oxide is larger than the absolute value of standard reaction Gibbs energy required to form an oxide with the second element included in the variable resistance layer, and
the second electrode is formed on insulator layer.

17. (canceled)

18. The method of claim 16, wherein the surface of the first electrode further comprises a plurality of convex features that each have different curvatures, and the variable resistance layer and the second electrode are formed over the plurality of convex features.

19. The method of claim 16, wherein forming the variable resistance layer further comprises forming a high oxygen concentration variable resistance layer within a region of the variable resistance layer, wherein the high oxygen concentration variable resistance layer has a larger oxygen concentration than an oxygen concentration of the variable resistance layer that is outside of the region.

20. The method of claim 16, wherein an oxygen concentration of the variable resistance layer increases in a direction extending from the second electrode to the first electrode.
